(19) United States
(12) Patent Application Publication
(10) Pub. No.: US 2026/0068186 A1
(43) Pub. Date: Mar. 5, 2026

(54) HIGH-BANDWIDTH MEMORY STACK WITH SIDE EDGE INTERCONNECTION AND LIQUID COOLING STRUCTURE

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW)

(21) Appl. No.: 19/386,015

(22) Filed: Nov. 11, 2025

Related U.S. Application Data
(63) Continuation-in-part of application No. 18/471,670, filed on Sep. 21, 2023.
(60) Provisional application No. 63/409,852, filed on Sep. 26, 2022.
(60) Provisional application No. 63/719,398, filed on Nov. 12, 2024.
(60) Provisional application No. 63/730,470, filed on Dec. 11, 2024.

(51) Int. Cl. H10B 80/00; H01L 25/00; H01L 25/065; H01L 25/18

(52) U.S. Cl. CPC H10B 80/00

(57) ABSTRACT

A semiconductor package structure includes a memory stack, a substrate, a processor die, and a liquid cooling structure. The memory stack includes a plurality of semiconductor dies horizontally separate with each other, wherein each semiconductor die has a top surface, a bottom surface, and four sidewalls, wherein the second sidewall is opposite to the first sidewall. A plurality of edge pads are arranged on the first sidewall of each semiconductor die. The substrate is under the memory stack and electrically connected to the plurality of edge pads of each of the semiconductor dies. The processor die is over the substrate and adjacent to the memory stack. The liquid cooling structure is over the memory stack and the processor die, and thermally coupled to both the memory stack and the processor die via the second sidewall of each of the semiconductor dies and the top surface of the processor die.

### PRIORITY CLAIM AND CROSS-REFERENCE

This application claims the benefit of U.S. provisional application No. 63/719,398 filed Nov. 12, 2024, U.S. provisional application No. 63/730,470 filed Dec. 11, 2024, and is a continuation-in-part application of U.S. non-provisional application No. Ser. No. 18/471,670 filed Sep. 21, 2023, which claims the benefit of U.S. provisional applications No. 63/409,852 filed Sep. 26, 2022, the disclosures of all of which are incorporated by reference herein in their entirety.

### FIELD OF THE INVENTION

This disclosure relates in general to a semiconductor package structure including a memory stack and a liquid cooling structure for the memory stack, and more particularly to a high-bandwidth memory stack with side edge interconnections and a liquid cooling structure for the high-bandwidth memory stack.

### BACKGROUND

As artificial intelligence (AI) and machine learning (ML) continue to transform various industries, AI chips (notably, general-purpose GPU for data centers) is poised for remarkable growth at 2.6× from 2024 to 2030 but also driving big shifts in their packaging needed to protect and connect these devices. Take NVIDIA's state-of-the-art GB200 GPU for instance, it draws as much as 1,200 W per chip and is likely to draw even higher power soon. The GB200 GPU is packaged in extreme 2.5D IC with HBMs (high-bandwidth memory stacks) placed laterally (side-by-side) with the GPU on an interposer and is direct-to-chip liquid cooled using a combination of thermal interface materials (TIMs), heat spreader and cold plate attached to the backside of the GPU and HBMs. Direct-to-chip liquid cooling is a thermal management technique where coolant is delivered directly to a cold plate that sits in direct contact with the processor or chip package.

Shown in FIG. 1 is a 2.5D IC structure 10 which comprises an HBM structure 11, which consists of a plurality of DRAM memory dies 111 and a controller 112 with TSVs (through-silicon vias) 101, a logic die 12 (such as a GPU or a SoC chip), a silicon interposer 13 with TSVs and a packaging substrate 14, wherein the HBM structure 11 and the logic die 12 are stacked on the silicon interposer 13 with the silicon interposer 13 stacked on the packaging substrate 14. Even though HBM involve far less power compared to the GPU, it also is expected to dissipate more heat as the HBM scales from HBM2E (19 W) to HBM4 (48/80 W) and beyond as the number of die in the HBM stack increases from 5 (for HBM2E) to 17 (for HBM4) and beyond. Power hungry and energy-intensive processors, particularly the GPU, produce significant heat, creating a critical challenge for data center operators. Efficient thermal management is also needed to ensure the dies in the HBM, particularly the bottom-tier and mid-tier dies in the HBM, maintain their optimum operation temperatures. Given the complexity and demands of AI workloads and the anticipated GPU and HBM power increase, the conventional cold-plate cooling will soon run out of steam: efficient thermal management is not an option; it is a necessity to ensure optimal performance and operational stability. Poor thermal management can lead to hardware degradation and downtime, performance bottlenecks and higher operational costs.

Besides the thermal challenges, going forward, HBM will be increasingly confronted with other issues including: (a) e xtreme costs pertaining to difficulties in getting high DRAM yields and lack of known-good die involving ever-higher numbers of costly through-silicon vias (TSVs); (b) a limited number of HBM suppliers; (c) lack of priority and support from these suppliers on HBM customization or optimization; (d) migration from flip chip based on copper pillar micro-bumps and molded underfill (MUF) to very costly copper hybrid bonding which is still in its nascent stage for future HBMs can dramatically increase the already high HBM costs; and (e) high-end advanced packaging capability and/or capacity are often the bottleneck at the existing suppliers big three which together impacts steady HBM supply.

### SUMMARY

According to a first aspect of the present disclosure, a semiconductor package structure includes a memory stack, a substrate, a processor die, and a liquid cooling structure. The memory stack includes a plurality of semiconductor dies horizontally separate from one another, wherein each semiconductor die comprises a top surface, a bottom surface opposite to the top surface, and four sidewalls with a first sidewall, a second sidewall, a third sidewall and a fourth sidewall, wherein the second sidewall is opposite to the first sidewall, and a plurality of edge pads arranged on the first sidewall of each semiconductor die; wherein the area of the bottom surface or the top surface is larger than that of any one of the four sidewalls. The substrate is under the memory stack and electrically connected to the plurality of edge pads of each of the semiconductor dies. The processor die is over the substrate and adjacent to the memory stack, and includes a top surface facing away from the substrate. The liquid cooling structure is over the memory stack and the processor die, and thermally coupled to both the memory stack and the processor die via the second sidewall of each of the semiconductor dies and the top surface of the processor die.

According to some embodiments of the present disclosure, the semiconductor package structure further includes a first heat spreader over the processor die, wherein a first surface of the first heat spreader facing towards the processor die is substantially leveled with the top surface of the processor die.

According to some embodiments of the present disclosure, the liquid cooling structure includes a cover over the first heat spreader, wherein the first heat spreader further includes a second surface facing the cover with a surface area of the second surface greater than a surface area of the first surface, wherein the cover and the first heat spreader together define a first cavity allowing a liquid coolant to flow through.

According to some embodiments of the present disclosure, the liquid cooling structure further includes a second heat spreader including a third surface facing the second sidewall of each of the semiconductor dies and a fourth surface opposite to the third surface with a surface area of the fourth surface greater than a surface area of the third surface, wherein the second heat spreader is configured to prevent the liquid coolant from contacting the second sidewall of each of the semiconductor dies, and wherein the cover and the second heat spreader together define a second cavity allowing the liquid coolant to flow through.

According to some embodiments of the present disclosure, the memory stack further comprises an adhesive layer between the top surface of a semiconductor die and the bottom surface of an adjacent semiconductor die.

According to some embodiments of the present disclosure, the second surface of the first heat spreader comprises a plurality of trenches extending in a direction of a flow of a liquid coolant.

According to some embodiments of the present disclosure, the liquid cooling structure includes a cover over the second sidewall of each of the semiconductor dies of the memory stack, wherein the cover and the memory stack together define a third cavity allowing the liquid coolant to flow through and contact the second sidewall of the semiconductor dies.

According to some embodiments of the present disclosure, the liquid cooling structure further comprises an inlet and an outlet.

According to some embodiments of the present disclosure, the semiconductor package structure further includes a bonding layer over the top surface of the processor die and configured to bond the processor die and the first surface of the first heat spreader.

According to some embodiments of the present disclosure, the memory stack further includes an upward extending high thermal conductivity layer between two adjacent semiconductor dies, wherein the thermal conductivity of the upward extending high thermal conductivity layer is higher than that of SiO₂.

According to a second aspect of the present disclosure, a semiconductor package structure includes a memory stack, a substrate, a processor die, and a liquid cooling structure. The memory stack includes a plurality of semiconductor dies horizontally separate from one another, wherein each semiconductor die includes a top surface, a bottom surface opposite to the top surface, and four sidewalls with a first sidewall, a second sidewall, a third sidewall and a fourth sidewall, wherein the second sidewall is opposite to the first sidewall, and a plurality of edge pads arranged on the first sidewall of each semiconductor die. The area of the bottom surface or the top surface of each semiconductor die is larger than that of any one of the four sidewalls. The substrate is under the memory stack and electrically connected to the plurality of edge pads on the first sidewall of each of the semiconductor dies. The processor die is over the substrate, comprising a top surface and a bottom surface opposite to the top surface, and adjacent to the memory stack, wherein the processor die and the memory stack define a height difference between the top surface of the processor die and the second sidewall of each of the semiconductor dies. The liquid cooling structure is over the memory stack and the processor die.

According to some embodiments of the present disclosure, the semiconductor package structure further includes a first heat spreader over the processor die, wherein a first surface of the first heat spreader facing the processor die is substantially coplanar with the top surface of the processor die.

According to some embodiments of the present disclosure, the liquid cooling structure includes a cover over the first heat spreader, wherein the first heat spreader further includes a second surface facing the cover with a surface area of the second surface greater than a surface area of the first surface, wherein the cover and the first heat spreader together define a cavity allowing a liquid coolant to flow through.

According to some embodiments of the present disclosure, the liquid cooling structure further includes a second heat spreader including a third surface facing the second sidewall of each of the semiconductor dies and a fourth surface opposite to the third surface with a surface area of the fourth surface greater than a surface area of the third surface, wherein the second heat spreader is configured to prevent a liquid coolant from contacting the second sidewall of each of the semiconductor dies.

According to some embodiments of the present disclosure, the liquid cooling structure includes a cover over the first heat spreader and the second sidewall of each of the semiconductor dies, wherein the cover, the first heat spreader and the memory stack together define a cavity allowing a liquid coolant to flow through.

According to some embodiments of the present disclosure, the semiconductor package structure further includes a memory controller die over the substrate and under the memory stack with the memory controller die electrically connected to the plurality of edge pads of each of the semiconductor dies.

According to some embodiments of the present disclosure, the semiconductor package structure further includes a memory controller die within the memory stack and over the substrate with the memory controller die electrically connected to the plurality of edge pads of each of the semiconductor dies.

According to some embodiments of the present disclosure, the substrate includes a laminate substrate and an interposer. The laminate substrate is under the memory stack and the processor die. The interposer is between the laminate substrate and the memory stack and the processor die, wherein the interposer comprises a plurality of through vias traversing the thickness of the interposer.

According to some embodiments of the present disclosure, the semiconductor package structure further includes a redistribution layer under the memory stack and electrically connected to the plurality of edge pads of each of the semiconductor dies.

According to some embodiments of the present disclosure, the substrate includes an embedded interconnection die electrically connecting the processor die and a portion of the plurality of edge pads of at least one of the semiconductor dies of the memory stack.

### BRIEF DESCRIPTION OF THE DRAWINGS

Aspects of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 shows a schematic diagram of a semiconductor 2.5D IC structure, according to a comparative embodiment of the present disclosure.

FIGS. 2A to 2E show schematic diagrams of a perspective view and side views of a semiconductor die with a side edge interconnection, respectively, according to some embodiments of the present disclosure.

FIGS. 2F to 2H show side views of a process of manufacturing a memory stack with side edge interconnections, according to some embodiments of the present disclosure.

FIGS. 3A to 3M show side views of intermediate stages of another process of manufacturing a memory stack with side edge interconnections, according to some embodiments of the present disclosure.

FIG. 4 shows a schematic diagram of another example of a memory stack with side edge interconnections, according to some embodiments of the present disclosure.

FIGS. 5A to 5D show schematic diagrams of a semiconductor package structure with a memory stack and a liquid cooling structure, according to some embodiments of the present disclosure.

FIGS. 6A to 6B show schematic diagrams of another semiconductor package structure with a memory stack and a liquid cooling structure, according to some embodiments of the present disclosure.

FIG. 7 shows a schematic diagram of still another semiconductor package structure with a memory stack and a liquid cooling structure, according to some embodiments of the present disclosure.

FIG. 8 shows a schematic diagram of yet another semiconductor package structure with a memory stack and a liquid cooling structure, according to some embodiments of the present disclosure.

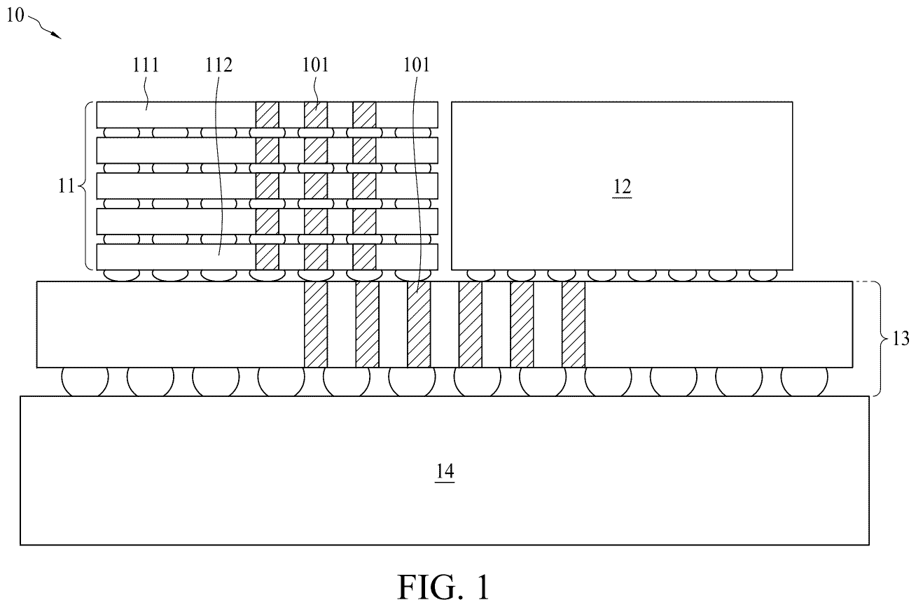

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

In the present disclosure, the side face(s) of memory dies are used for interconnecting dies in the 2.5D (or 3D) IC stack to allow for signal and power distribution. Moreover, a high thermal conductivity material is disposed between two adjacent dies and thermally coupled to another high thermal conductivity material covering a side face of the memory stack.

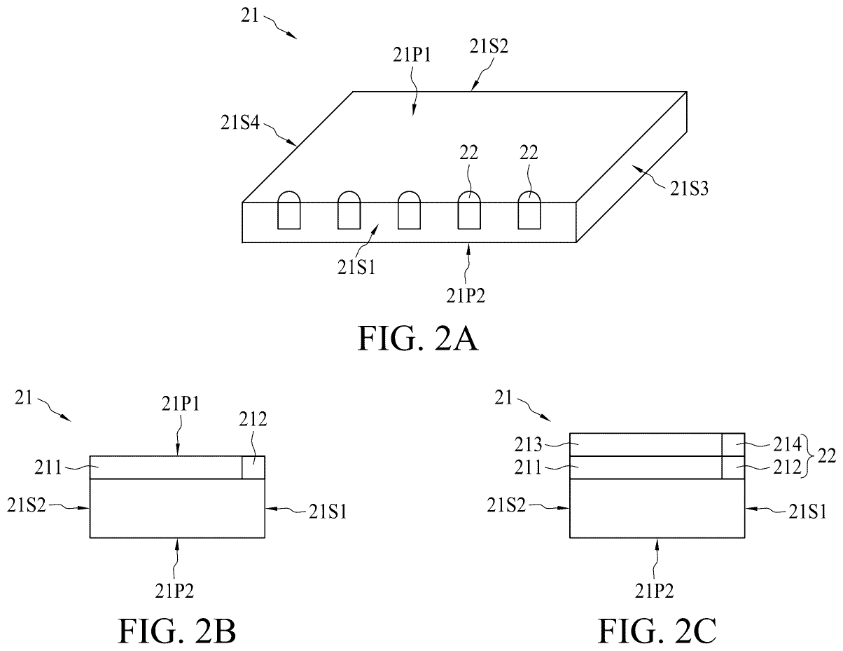

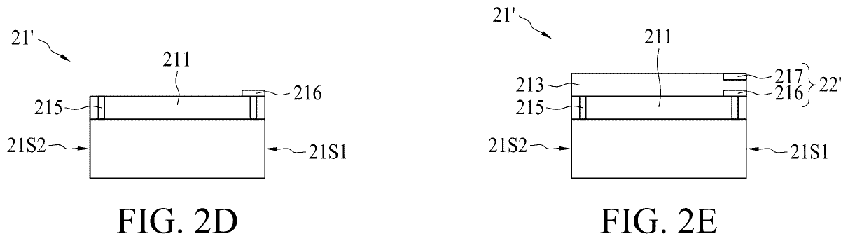

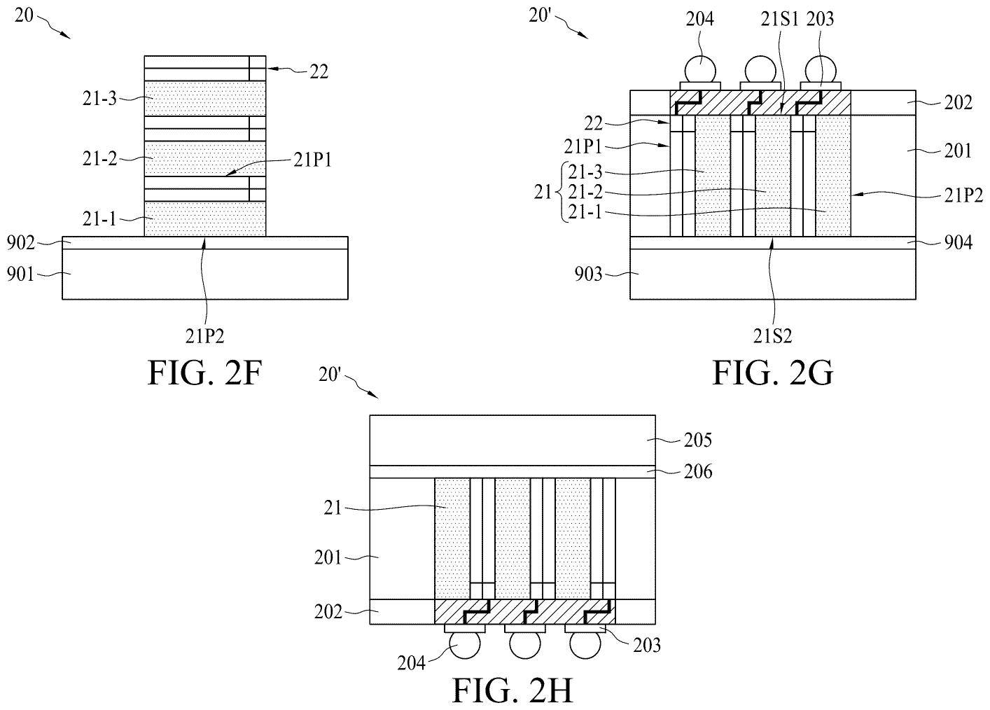

FIGS. 2A to 2E show schematic diagrams of a perspective view and side views of a semiconductor die with a side edge interconnection, respectively, according to some embodiments of the present disclosure. FIG. 2A shows a perspective view of a semiconductor die 21 according to some embodiments of the present disclosure. In some embodiments, the semiconductor die 21 can include a top surface 21P1, a bottom surface 21P2 opposite to the top surface 21P1, and four sidewalls (side surfaces) including a first sidewall 21S1, a second sidewall 21S2, a third sidewall 21S3 and a fourth sidewall 21S4. A plurality of edge pads 22 can be arranged on the first sidewall 21S1 of each semiconductor die 21, wherein the area of the bottom surface 21P2 or the top surface 21P1 is larger than that of any one of the four sidewalls (side surfaces) from 21S1 to 21S4. In some embodiments, the semiconductor die 21 can include a memory die (e.g., DRAM die), a memory chiplet, a control IC, a control IC chiplet, a processor, a processor chiplet, or another suitable die or its chiplet.

FIG. 2B shows a side view of a semiconductor die 21, according to some embodiments of the present disclosure. In some embodiments, a conductive via (edge via) 212 is formed in a back-end-of-line (BEOL) region 211 of the semiconductor die 21, in which the conductive via 212 can be configured for edge connection from the first sidewall 21S1 (side surface) of the semiconductor die 21. Throughout the present disclosure, the term “BEOL” refers to the second major phase of semiconductor manufacturing, following the front-end-of-line (FEOL). The formation of the BEOL involves the creation of metal interconnects (not separately shown) that connect the transistors and other active devices built during FEOL. Therefore, the active devices (not shown) formed in the semiconductor die 21 are electrically connected to the edge via 212 through the metal interconnects of BEOL, and can be connected to other external devices through the edge via 212 formed on the side surface 21S1 of the semiconductor die 21.

FIG. 2C shows a side view of the semiconductor die 21, in which a redistribution layer (RDL) 213 is formed on the semiconductor die 21 on its BEOL 211. The number of metal layers in the RDL, the thickness of the BEOL in the semiconductor die 21 and the routing configuration of between the BEOL and the RDL may vary according to design requirements. In some embodiments, to increase the side contact area of the edge via 212, another conductive via 214 is formed inside the RDL 213 right above the edge via 212, so as to form a large edge conductive feature (edge pad) 22 for interconnection on the first sidewall 21S1 of the semiconductor die 21. The edge conductive feature (edge pad 22) including the edge vias 212 and 214 can have a greater side contact area than the side contact area of the standalone edge via 212 for ease of subsequent interconnection. In some embodiments, the RDL 213 is optional. In some embodiments, the edge via 214 is optional. That is, the edge via 212 can be configured alone to form the edge pad 22. In some embodiments, the RDL 213 can be formed on both the top and bottom surfaces of the semiconductor die 21. In some embodiments, an edge pad can be formed on the BEOL and/or on the RDL to further increase the interconnection areas over the side edge. Moreover, besides the edge pads above, edge pads can also be formed inside the semiconductor die 21 in the form of, for example, a partial though silicon via (TSV; or a via inside the silicon) or a complete TSV which traverses the silicon thickness to further enlarge the area for interconnection. In some embodiments, the semiconductor die 21 can contain more than one die interconnected by the RDL 213 using a fan-out packaging process with the die assembly containing edge pads. In some embodiments, the semiconductor die 21 can contain a plurality of dies arranged side-by-side and/or one on top of the other in the package thickness direction. When a fan-out process is used to integrate a plurality of dies, edge pad can also appear in the form of a partial through-mold via (TMV) or a complete TMV which traverses the molding compound thickness.

FIG. 2D shows a side view of a semiconductor die 21′, according to some embodiments of the present disclosure. The semiconductor die 21′ is similar to the semiconductor die 21 shown in FIG. 2C in many aspects. In some embodiments, an edge pad 216 is formed on a top surface of the BEOL 211 of the semiconductor die 21′. The edge pad 216 can be a thick edge pad 216 and configured for edge connection from the first sidewall 21S1 (side surface) of the semiconductor die 21′. In some embodiments, the BEOL 211 of the semiconductor die 21′ can include a seal ring structure 215 which surrounds the active region of the respective semiconductor die 21′.

FIG. 2E shows a side view of the semiconductor die 21′, in which an RDL 213 is formed on the semiconductor die 21′. In some embodiments, to increase the interconnection area of the edge pad 216, the RDL 213 is formed on the BEOL region 211 of the semiconductor die 21′ with another edge via 217 formed right above the edge pad 216, so as to form a larger edge conductive feature (edge pad 22′) on the first sidewall 21S1 of the semiconductor die 21′. The edge conductive feature (edge pad 22′) including the edge pads 216 and 217 can have a greater side contact area than the contact area of the standalone edge pad 216. In some embodiments, the RDL 213 is optional. In some embodiments, the edge pad 217 is optional. That is, the edge pad 216 can be configured alone to form the edge pad 22′. In the present disclosure, the semiconductor die or memory die in the memory stack can be based on the semiconductor die 21 shown in FIG. 2A to FIG. 2C, the semiconductor die 21′ shown in FIG. 2D and FIG. 2E, and though not shown the semiconductor die comprising a plurality of dies with or without the partial TSVs, complete TSVs, partial TMVs, complete TMVs, etc.

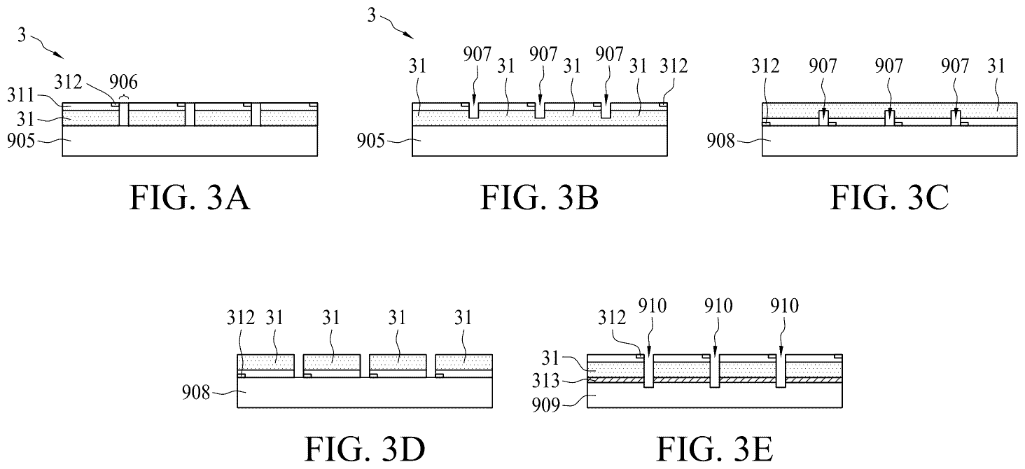

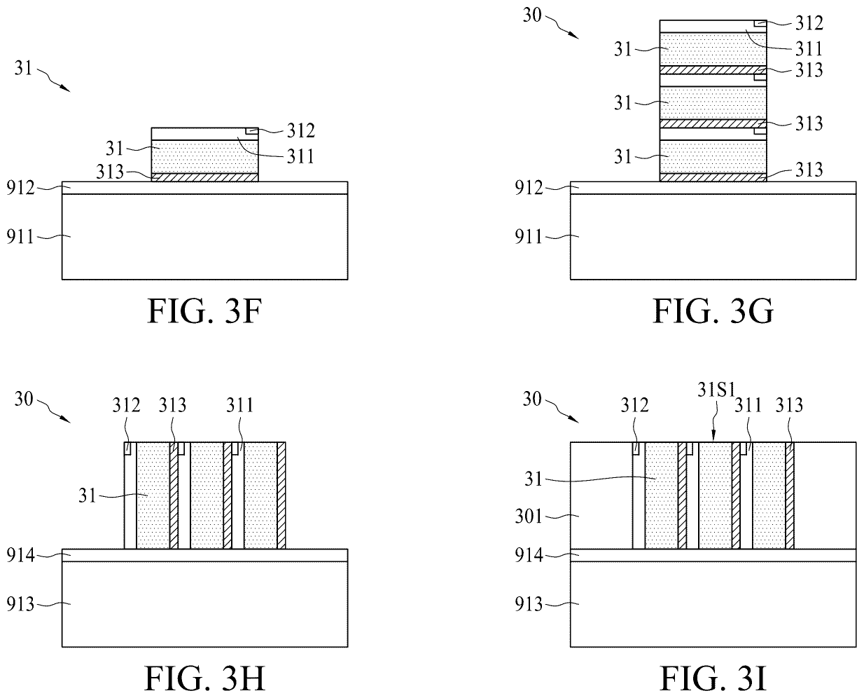

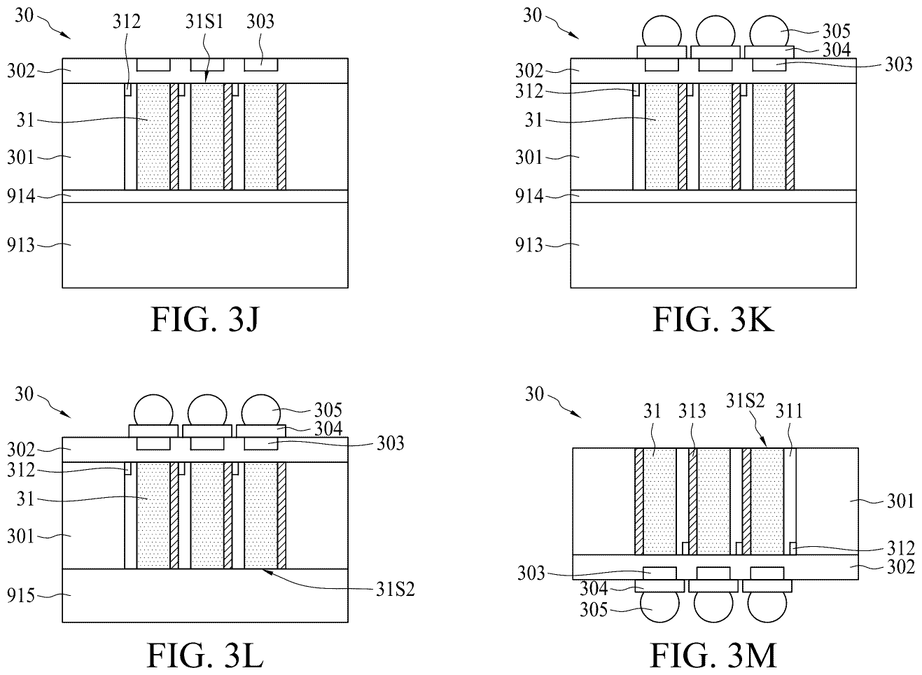

FIG. 2F shows a side view of an intermediate stage of forming a memory stack 20 by stacking a plurality of semiconductor dies (memory dies) 21 or 21′ shown in FIG. 2A to FIG. 2E. In some embodiments, a first semiconductor die 21-1 is placed on a carrier 901. The bottom surface 21P2 of the first semiconductor die 21-1 is attached to a temporary carrier 901 through a release layer 902. In some embodiments, the carrier 901 is a glass carrier, and the release layer 902 is a sacrificial layer which is used in the separation of the memory stack 20 from the carrier 901. In some embodiments, a second semiconductor die 21-2 is placed on and attached to the first semiconductor die 21-1, and a third semiconductor die 21-3 is placed on and attached to the second semiconductor die 21-2. For example, an adhesive or a bonding layer (not shown in FIG. 2A, but labelled as 313 in FIGS. 3F to 3I) is deposited on the top surface 21P1 (see FIG. 2A) of the first semiconductor die 21-1 such that the bottom surface 21P2 (see FIG. 2A) of the second semiconductor die 21-2 can be attached to the top surface 21P1 of the first semiconductor die 21-1. In some embodiments, a bonding layer (not shown in FIG. 2A, but labelled as 313 in FIGS. 3F to 3I) can be formed between the top surface 21P1 (see FIG. 2A) of the first semiconductor die 21-1 and the bottom surface 21P2 (see FIG. 2A) of the second semiconductor die 21-2 free of the adhesion layer. For example, another RDL can be formed on the bottom surface 21P2 of the second semiconductor die 21-2, and the RDL located at the top surface 21P1 of the first semiconductor die 21-1 can be bonded to the RDL located at the bottom surface 21P2 of the second semiconductor die 21-2 through a flip chip or copper hybrid bonding process. According to some embodiments, an oxide-oxide bond and a metal-metal bond are formed at an interface between the oxide layers and metallic layers in of the bonded RDLs. The oxide-oxide bond formed in the bonding layer can be waterproof, thereby protecting the interface between the first semiconductor die 21-1 and the second semiconductor die 21-2 from water intrusion. The same procedures can be repeated to integrate more than 3 semiconductor dies 21 to form a memory stack 20. In some embodiments, the memory stack 20 can be a new or a custom high-bandwidth memory (NuHBM) stack or shelf.

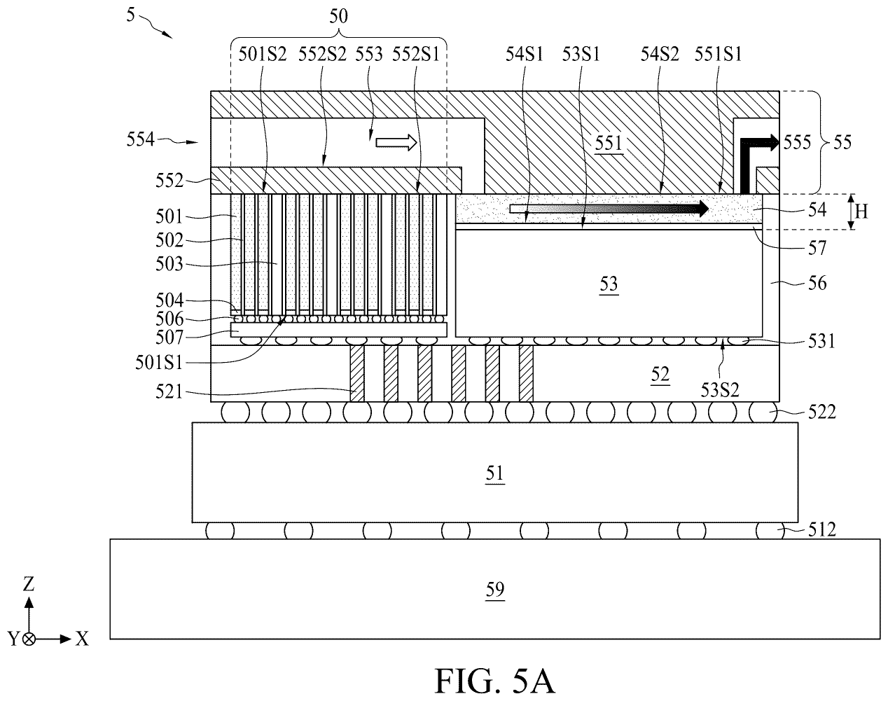

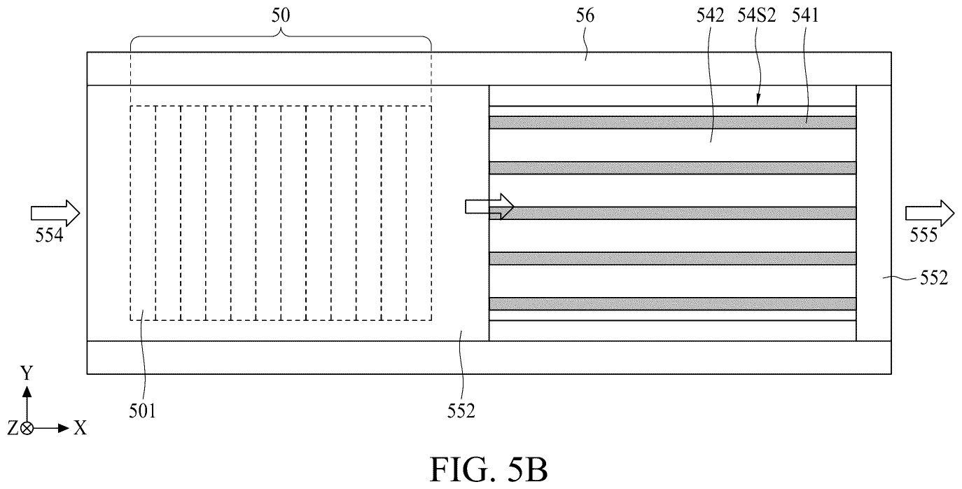

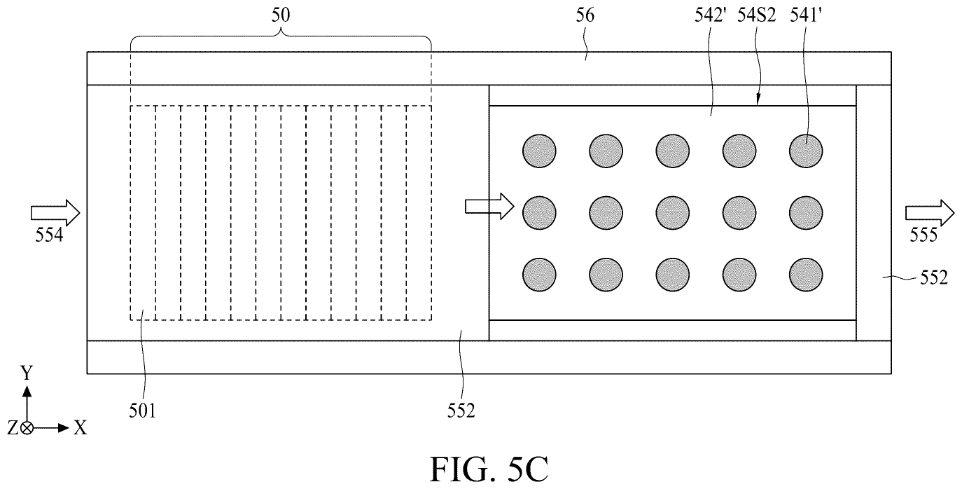

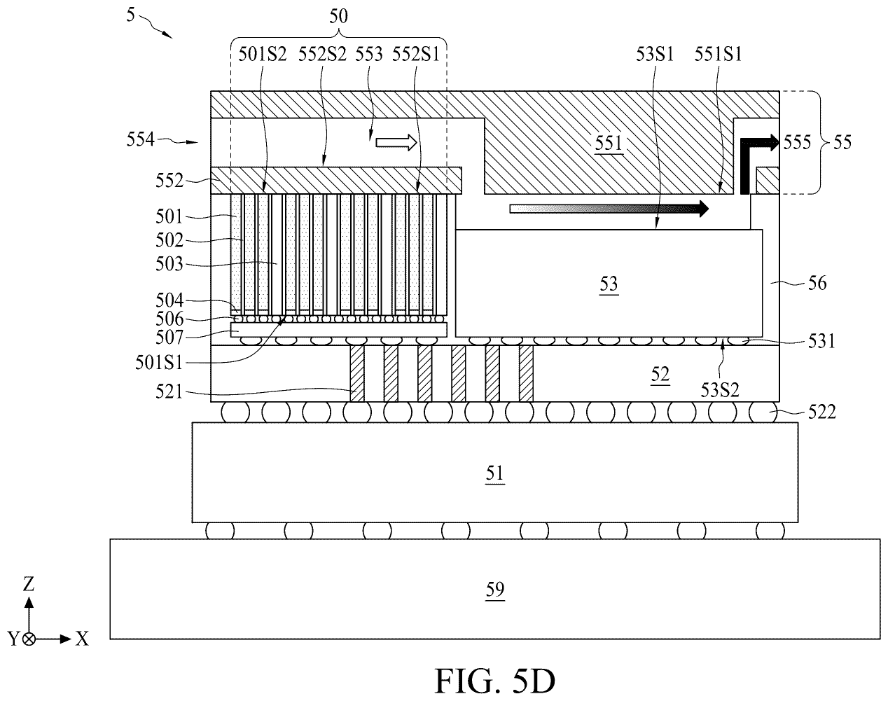

In some embodiments, as the number of semiconductors die 21 in the memory stack 20 increases, the multiple semiconductor dies 21 can be divided into several groups, and each group can be separated by a thermal interface material or a high-thermal conductivity (TIM) layer. In some embodiments, the TIM layer can be applied between every pair of adjacent semiconductor dies 21. The introduction of the TIM layer further aids in heat dissipation of the semiconductor dies 21, as explained in the embodiments illustrated in FIG. 5A to FIG. 8 of the present disclosure.

Referring to FIG. 2G, according to some embodiments of the present disclosure, after the plurality of semiconductor dies 21 are stacked into the memory stack 20, the memory stack 20 is released from the carrier 901 and placed on another carrier 903 on a sidewall to reconstitute a memory stack 20′ with the second sidewall 21S2 of each semiconductor die 21 attached to the carrier 903. For each semiconductor die 21 within the memory stack 20′, the first sidewall 21S1 faces in a direction away from the carrier 903, wherein the edge pads 22 are arranged on the first sidewall 21S1 of the semiconductor dies 21. For each semiconductor die 21 within the memory stack 20′, the second sidewall 21S2 faces toward the carrier 903 and is attached to the carrier 903. The materials and features of the carrier 903 and the release layer 904 can be basically similar to those of the carrier 901 and the release layer 902 described above.

Next, a molding material 201 is formed on the carrier 903 to surround the multiple semiconductor dies 21. The molding material 201 may be a potting material or a molding compound. In some embodiments, the molding material 201 surrounds the memory stack 20′. For example, the molding material 201 can surround the top surface 21P1 of the third semiconductor die 21-3, the bottom surface 21P2 of the first semiconductor die 21-1, and the third sidewall 21S3 and the fourth sidewall 21S4 of each of the semiconductor dies 21 (as illustrated in combination FIG. 2A and FIG. 2G). Note that the number of semiconductor die 21 in the memory stacks 20′ shown in FIG. 2F and FIG. 2G merely serves as an example, and the present disclosure is not limited thereto.

After the molding material 201 is formed, a planarization operation is performed on the first sidewall 21S1 of each of the semiconductor dies 21 of the memory stack 20′ and the molding material 201 to create a flat side surface (FSS) of the memory stack 20′. Here, the FSS of the memory stack 20′ is defined by the first sidewall 21S1 of the semiconductor dies 21 after planarization. Then, an RDL 202 is deposited on the FSS surface of the memory stack 20′. In some embodiments, the RDL 202 can be deposited on and interconnecting a plurality of memory stack 20′, wherein each memory stack 20′ is separated by the molding material 201. In some embodiments, the RDL 202 is a thin dielectric/metal interconnect layer added to the FSS surface of the memory stack 20′ to reroute the electrical connections of the memory stack 20′, allowing interconnection of the edge pads of the semiconductor dies 21 to overlying bumps, micro-pillars, or recessed copper pads for copper hybrid bonding for mounting the memory stacks 21′ onto an interposer, a substrate, a PCB, or a combination thereof. In some embodiments, the dielectric of the RDL 202 may include a dielectric such as polyimide, oxide (such as silicon dioxide) or a combination, and the interconnect or the metal layers of the RDL 202 may include copper. Some detailed descriptions can be found in paragraphs with reference to FIG. 3I to FIG. 3M.

In some embodiments, the RDL 202 can include a wiring portion (shown with slash lines) located right above the semiconductor dies 21 and a non-wiring portion (areas without the slashed lines) located right above the molding material 201. In some embodiments, under-bump metallization 203 and conductive bumps 204 are formed successively on the RDL 202, and the RDL 202 is configured to electrically connect the edge pads of each semiconductor die 21 to the corresponding conductive bumps 204. The RDL 202 and the conductive bumps 204 may constitute a fan-out structure for the edge pads of the semiconductor dies 21, thereby enabling a larger connection pitch and a high-yielding RDL process for the memory stack 20′.

FIG. 2H shows a final stage of forming the memory stack 20′, according to some embodiments of the present disclosure. After the RDL 202, the UBM 203 and the conductive bump 204 are formed on the FSS of the memory stack 20′, the memory stack 20′ is released from the carrier 903. In some embodiments, the memory stacks 20′ are diced and the excess molding material 201 is removed. In some embodiments, a thermal interface or a high-thermal-conductivity-material layer (TIM) 206 is applied to the surface of a sidewall (SWW) opposite to the FSS of the memory stack 20′, and a heat sink 205 is attached to the TIM 206, allowing heat generated from each semiconductor die 21 to be dissipated through the SWW of each semiconductor die 21 in contact with the TIM 206. In contrast, conventional vertically HBMs face issues that the IC chips located in the middle and bottom layers can only dissipate heat through the top surface of the memory stack. Therefore, the heat dissipation efficiency of the present disclosure can be improved significantly.

FIGS. 3A to 3M show side views of intermediate stags of a process of manufacturing a memory stack 30 with side edge interconnections, according to some embodiments of the present disclosure. For the sake of brevity, some repetitive descriptions described previously may be omitted. FIG. 3A shows a wafer 3 containing a plurality of semiconductor dies 31, wherein the wafer 3 is disposed on a dicing tape 905. In some embodiments, a RDL 311 is formed on a wafer for each semiconductor die 31, wherein the RDL 311 can include an edge pad 312 exposed from the sidewall of each semiconductor die 31. In some embodiments, the BEOL region of each semiconductor die 31 can include a seal ring (not shown) which surrounds the active region of the respective semiconductor die 31, and the edge pad 312 can be formed over the seal ring of each semiconductor die 31 in the absence of the RDL 311. In some embodiments, a dicing street 906 is defined between adjacent semiconductor dies 31 for subsequent dicing operation.

FIG. 3B shows a side view of the semiconductor dies 31, according to some embodiments of the present disclosure. The semiconductor dies 31 are subject to a dicing process, in which a processed wafer 3 is cut into individual semiconductor dies. The dicing process can include but not limited to, blade dicing (also referred to as mechanical sawing, which uses a high-speed rotating diamond blade to cut the wafer), laser dicing (which uses a focused laser beam to cut or weaken materials), and plasma dicing (which uses deep reactive ion etching with masks to etch narrow trenches between dies). In some embodiments, a plurality of partial cuts 907 are formed on the front surface of the wafer 3 along each dicing street 906. In some embodiments, the edge pad 312 of each semiconductor die 31 is exposed from the partial cut 907.

FIG. 3C shows a side view of the semiconductor dies 31, according to some embodiments of the present disclosure. After the partial cut s 907 are formed on the front surface of the wafer 3, the wafer 3 is flipped and attached to a back grinding tape 908 and the dicing tape is released. That is, the front surface (i.e., the active side) of the wafer 3 is attached to the back-grinding tape 908, and the partial cuts 907 form a plurality of openings between the back-grinding tape 908 and the wafer.

FIG. 3D shows a side view of the semiconductor dies 31, according to some embodiments of the present disclosure. In some embodiments, a grinding or thinning process is performed on the back surface of the wafer 3. During the grinding process, the thickness of the wafer decreases until the openings formed by the partial cuts 907 are revealed, and the semiconductor dies 31 are separated by the partial cut s 907.

FIG. 3E shows a side view of the semiconductor dies 31, according to some embodiments of the present disclosure. After the semiconductor dies 31 are separated, a dicing tape 909 and an adhesion layer 313 are attached to the back surface of the semiconductor dies 31, and the back-grinding tape 908 is removed from the front surface of the semiconductor dies 31. For example, the adhesion layer 313 can be a die attach film (DAF). In some embodiments, the adhesion layer 313 is cut into multiple sections corresponding to the semiconductor dies 31 by cuts 910 wherein the cuts 910 may be formed using a laser cutting process.

Referring to FIG. 3F, in some embodiments, a semiconductor die 31 is released from the dicing tape in FIG. 3E and attached to a carrier 911 through a release layer 912. Referring to FIG. 3G, multiple semiconductor dies 31 are stacked into a memory stack 30 on the carrier 911 using the adhesive layers 313 as the bonding layer between adjacent dies (or die stacks). Referring to FIG. 3H, the memory stack 30 is released from the carrier 911 and placed using a release layer 914 on another carrier 913 on a sidewall opposite to the edge pad 312. In some embodiments, a plurality of memory stacks 30 can be placed on the carrier 913 and spaced apart from each other. FIG. 3I shows a side view of the formation of the molding material 301 over the carrier 913 and surrounding the semiconductor dies 31. In some embodiments, the molding material 301 is polished and leveled with the sidewall 31S1 of the semiconductor dies 31 by a chemical planarization process (CMP) or a back-grinding process. In some embodiments, a plurality of memory stacks 30 can be separated from each other by the molding material 301.

Referring to FIG. 3J, in some embodiments, an RDL 302 is formed on the first sidewall 31S1 of each of the semiconductor dies 31 of the memory stack 30 using a fan-out process. In some embodiments, the RDL 302 includes bond pads 303 respectively connected to the edge pads 312 of the semiconductor dies 31. Referring to FIG. 3K, an under-bump metallization (UBM) 304 is deposited on the bond pad 303, and conductive bumps 305 are deposited on the UBM 304. In some embodiments, the surface of the memory stack 30 that has the conductive bumps is attached to a UV tape (not shown), and the carrier 913 is released from the memory stack 30. Referring to FIG. 3L, a dicing tape 915 is attached to the second sidewall 31S2 of each of the semiconductor dies 31 of the memory stack 30, and the memory stack 30 is released from the UV tape. Referring to FIG. 3M, the memory stack 30 on the dicing tape 915 is diced and the excess molding material 301 is removed. In some embodiments, the plurality of memory stacks 30 placed on the dicing tape 915 can be diced into individual memory stacks 30 by cutting through the molding material 301. This process can be referred to as a singulation or dicing process. In some embodiments, a thermal interface material (TIM) layer (not shown) can be applied to the second sidewalls 31S2 of each of the semiconductor dies 31 of the memory stack 30, and a heat sink (not shown) can be attached to the TIM layer. Therefore, heat generated from each semiconductor die 31 can be dissipated through the second sidewall 31S2 of each semiconductor die 31 in contact with the TIM layer.

In some embodiments, the singulation process can be performed without needing to form the RDL 302 on the first sidewall 31S1 of each of the semiconductor dies 31 for direct interconnection to the edge pads. Referring to FIG. 3I, after reconstituting a plurality of memory stacks 30 on the carrier 913 and surrounding each memory stack 30 with the molding material 301, the memory stacks 30 can be placed on a dicing tape (not shown) for a subsequent dicing process (singulation process).

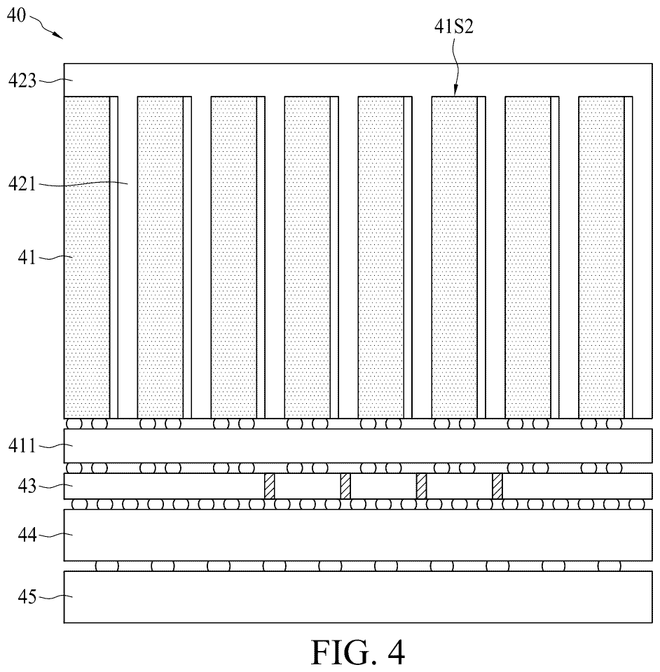

FIG. 4 shows a side view of another example of a memory stack 40 with side edge interconnections, according to some embodiments of the present disclosure. Based on the aforementioned processes, multiple DRAM dies 41 can be bonded to a carrier to form several DRAM memory stacks 40 or shelves, wherein each DRAM memory stack 40 includes a set of DRAM dies 41, and an upward extending HTC layer 421 between adjacent DRAM dies 41, e.g., made of a TIM, diamond, AlN, SiC, BN, BAs, Cu, W, or a combination thereof between every two adjacent DRAM dies 41 for thermal enhancement. In some embodiments, the upward extending HTC layer 421 can extend to the second sidewall 41S2 of each of the DRAM dies 41 of the memory stack 40 and form a lateral extending high thermal conductivity layer 423 which is thermally coupled with an HTC heat spreader for thermal enhancement.

The DRAM memory stack 40 can be bonded to a memory controller 43, an IC chip, an interposer 44, a laminate substrate or a combination through a RDL such as the RDL 411 and the edge pads of the DRAM memory stack 40 as described above. The interposer 44 can be bonded to a laminated substrate or a PCB (printed circuit board) 45. The DRAM memory stack 40 includes a plurality of DRAM dies 41, and each DRAM die 41 is horizontally separate from the others. As shown in FIG. 4, the power/signaling of each DRAM die 41 could be transmitted to the controller die (memory controller 43) without running through other DRAM dies in the case of HBMs. Moreover, since there is upward extending HTC layer 421 between two adjacent DRAM dies 41 (and even between two adjacent dies in a memory stack) and connected to a laterally extending high thermal conductivity layer 423 on the second sidewall(s) of the DRAM dies 41, heat generated from those two adjacent DRAM dies 41 could be spread through the upward extending high thermal conductivity layer 421 to the lateral extending high thermal conductivity layer 423, and passed to a heat spreader, a vapor chamber, a cold plate, a heatsink, or a combination thereof.

FIGS. 5A and 5B show a side view and a top view, respectively, of a semiconductor package structure 5 with a memory stack 50 and a liquid cooling structure 55, according to some embodiments of the present disclosure.

Referring to FIG. 5A, the semiconductor package structure 5 includes the memory stack 50, a first substrate 51, an interposer 52, a processor die 53, the liquid cooling structure 55, and a second substrate 59. The memory stack 50 includes a plurality of semiconductor dies 501 horizontally separate from one another, wherein each semiconductor die 501 (referring to FIG. 2A) has a top surface, a bottom surface opposite to the top surface, and four sidewalls including a first sidewall 501S1, a second sidewall 501S2, a third sidewall and a fourth sidewall, wherein the second sidewall 501S2 is opposite to the first sidewall 501S1, and a plurality of edge pads 504 arranged on the first sidewall 501S1 of each semiconductor die 501. The area of the bottom surface or the top surface of each semiconductor die 501 is larger than that of anyone of the four sidewalls. The first substrate 51, the second substrate 59, and the interposer 52 are arranged under the memory stack 50 and electrically connected to the memory stack 50 through the plurality of edge pads 504 of each of the semiconductor dies 501.

The processor die 53 is arranged over the first substrate 51, the second substrate 59 or the interposer 52, and is adjacent to the memory stack 50. The processor die 53 has a top surface 53S1 and a bottom surface 53S2 opposite to the top surface 53S1. In some embodiments, the bottom surface 53S2 of the processor die 53 faces toward the first substrate 51, the second substrate 59, the interposer 52, or a combination thereof. In some embodiments, the processor die 53 has a thickness about 750 micrometers (μm) measured in the Z-direction, a width about 3.3 cm measured in the Y-direction, and a length about 2.6 cm measured in the X-direction. The liquid cooling structure 55 is arranged over the memory stack 50 and the processor die 53, and thermally coupled to both the memory stack 50 and the processor die 53 via the second sidewall 501S2 of each of the semiconductor dies 501 and the top surface 53S1 of the processor die 53.

The memory stack 50 can be substantially the same as the memory stack 20, 20′, 30 or 40 described in FIG. 2A to FIG. 4. In some embodiments, the semiconductor dies 501 of the memory stack 50 can include memory dies (e.g., DRAM dies), processor dies, controller IC dies, and/or other logic ICs.

In the present disclosure, the term “substrate” can include one or more of the first substrate 51, the interposer 52, and the second substrate 59, or a combination thereof. In some embodiments, the first substrate 51 can be a laminate substrate, such as a build-up substrate based on ABF (Ajinomoto Build-up Film). In some embodiments, the laminate substrate includes base or core materials, usually a flat sheet made from layers of resin and reinforcing fibers (e.g., glass fiber cloth and epoxy). In some embodiments, the first substrate 51 can be a glass or a glass-core substrate with features similar to those of the laminate substrate. In some embodiments, the second substrate 59 can be a package substrate, such as a printed circuit board (PCB) substrate. In 2.5D IC, the interposer 52 is arranged between the laminate substrate 51 and the memory stack 50 and the processor die 53. In some embodiments, the interposer 52 can be a silicon interposer, a glass interposer, a metal interposer, a fan-out interposer or a combination thereof with RDLs and conductive through vias 521 traversing the thickness of the interposer 52 wherein the RDL can be based on low-Dₖ/D_{f} material/Cu, polyimide/Cu, ABF-like/Cu, oxide/Cu, nitride/Cu or a combination thereof. In some embodiments, the interposer 52 includes a plurality of bumps 522 connected to the first substrate 51, and the first substrate 51 includes a plurality of bumps 512 connected to the second substrate 59. The interposer 52 is used for electrical connection between the semiconductor chips (semiconductor die 501 and the processor die 53) and the first substrate 51. In some embodiments, the laminate substrate 51 can be optionally integrated with the package substrate 59 to form a hybrid substrate containing features from the first and the second substrates. In some embodiments, the memory stack 50 (or the memory controller 507) and the processor die 53 can be directly disposed on the package substrate 59. In some embodiments, the laminate substrate 51 can also be integrated with the interposer 52 to form a hybrid substrate with conductive vias. Even though 2.5D IC is used throughout this disclosure, the present disclosure is not limited thereto.

In some embodiments, options of the processor die 53 can include graphics processing unit (GPU), custom application-specific IC (ASIC), central processing unit (CPU), network processing unit (NPU), tensor processing unit (TPU), field-programmable gate array (FPGA), etc. In some embodiments, the memory controller die 507 can be optional as it may be integrated with the memory dies in the lateral memory stack, and the processor die 53 can include built-in memory control functions connected to the edge pads of each semiconductor die 501 through the interposer 52, the first substrate 51, etc. As illustrated in FIG. 5A, the processor die 53 is arranged over the first substrate 51 and the interposer 52 and adjacent to the memory stack 50, wherein the processor die 53 and the memory stack 50 defines a height difference H between a top surface 53S1 of the processor die 53 and the second sidewall 501S2 of each semiconductor die 501, wherein the second sidewall 501S2 is opposite to the first sidewall 501S1.

In some embodiments, the memory stack 50 includes a plurality of semiconductor dies 501 horizontally separate from one another, and each semiconductor die 501 includes edge pads 504 arranged on the first sidewall 501S1 of the semiconductor die 501 for electrical interconnection between the semiconductor dies 501 and the memory controller die 507. The detailed description about the formation of the edge pads 504 can be found with reference to FIG. 2A to FIG. 4 of the present disclosure. In some embodiments, the memory stack 50 includes adhesion layers 502 (e.g., HTC layers) disposed between adjacent semiconductor dies 501, wherein the adhesion layers 502 can include organic and inorganic materials. In some embodiments, the semiconductor die 501 (memory IC) has a length about 5.25 mm measured in the Z-direction and a width about 9.5 mm measured in the Y-direction). In some embodiments, a semiconductor die 501 has a thickness measured in the X-direction) about 515 μm, and the entire thickness of each semiconductor die 501 can be used for edge connection, In some embodiments, the disclosed massively parallel 3D memory or lateral memory stack including 16 or 20 semiconductor dies 501 bonded to the memory controller die 507 can provide an enough chip side-surface area to accommodate 5,440 inputs/outputs (I/Os) per semiconductor die 501, that is a total of 87,040 or 108,800 I/Os (assuming a bump pitch of 29 μm). In some embodiments, the edge pads 504 can be configured to transmit power and signal.

As the requirements for performance and bandwidth of the memory stack 50 increase, the number of the semiconductor dies 501 (DRAM die) in one memory stack 50 tends to also increase, resulting in more challenging thermal management requirements. For example, the HBM3 (High Bandwidth Memory 3), HBM4 (High Bandwidth Memory 4), and HBM5 standards are advanced memory standards designed for high-speed, high-capacity, and energy-efficient memory used in applications including, AI and machine learning (e.g., GPUs, accelerators), HPC (high-performance computing), networking and data centers. For HBM3, it can contain 12 semiconductor dies 501 in one memory stack 50. For the HBM4 node, one memory stack 50 can up to 16 semiconductor dies 501 while for the HBM5, it can include even more semiconductor dies 501. With the increasing number of semiconductor dies 501 stacked in a single memory stack 50, concerns about overheating in the middle and bottom memory tiers inevitably arise.

In some embodiments, the liquid cooling structure 55 is disposed over the memory stack 50 and the processor die 53, and thermally coupled to the second sidewall 501S2 of each of the semiconductor dies 501 and the top surface 53S1 of the processor die 53. In some embodiments, heat generated by each semiconductor die 501 can be conducted through the second sidewall 501S2 of each semiconductor die 501 to the liquid cooling structure 55. That is, heat generated by each semiconductor die 501 can be conducted through silicon rather than a combination of silicon and the poorly heat dissipating silicon dioxide in the BEOL layers of each memory die of conventional HBMs. In some embodiments, the thermal conductivity of silicon can be up to 100 times greater than that of silicon dioxide.

In some embodiments, as the number of semiconductor dies 501 in a memory stack 50 increases, the multiple semiconductor dies 501 can be divided into several groups, and each group can be separated by TIM layers 503. For example, as shown in FIG. 5A, the memory stack 50 can include an upward extending HTC TIM layer 503 within the memory stack 50, wherein the thermal conductivity of the upward extending high thermal conductivity layer (TIM layer 503) is higher than that of SiO₂. In some embodiments, the upward extending HTC TIM layer 503 is disposed between every two adjacent semiconductor dies 501.

In some embodiments, the memory stack 50 can include a RDL (not shown in FIG. 5A) disposed on the first sidewall 501S1 of the semiconductor die 501, in a manner similar to the RDL 302 illustrated in FIG. 3J to FIG. 3M. In some embodiments where an RDL is present on the memory stack 50, such RDL can include a plurality of conductive bumps 506. The conductive bumps 506 can correspond to the conductive bumps 305 illustrated in FIG. 3J to FIG. 3M. The RDL and the conductive bumps 506 can be configured to connect to the edge pads 504, and the next-level component, whether it be the interposer 52, first substrate 51, etc. while helping to increase the bonding pad pitch of the memory stack 50 accordingly.

In some embodiments, the memory controller die 507 is disposed over the first substrate 51, the second substrate 59 or the interposer 52, and under the memory stack 50. In some embodiments, the memory controller die 507 is electrically connected to the plurality of edge pads 504 of each of the semiconductor dies 501 in the memory stack 50 through the conductive bumps 506.

In some embodiments, the semiconductor package structure 5 further includes a first heat spreader 54 over the processor die 53, wherein a first surface 54S1 of the first heat spreader 54 facing towards the processor die 53 is substantially leveled with the top surface 53S1 of the processor die 53 opposite to the bottom surface 53S2. In other words, the first surface 54S1 of the first heat spreader 54 facing the processor die 53 is substantially coplanar with the top surface 53S1 of the processor die 53 opposite to the bottom surface 53S2. The first heat spreader 54 can include a microstructure, such as fins, trenches, or channels, to maximize surface area of the second surface 54S2 allowing the liquid coolant to flow through. In some embodiments, the first heat spreader 54 can be a finned silicon structure, of which the microstructure is manufactured through a photolithography process. In some embodiments, the first heat spreader 54 can be a metal plate. A bonding layer can be disposed over the top surface 53S1 of the processor die 53 and configured to bond the processor die 53 to the first surface 54S1 of the first heat spreader 54.

When the silicon fin structure is used as the first heat spreader 54, the first heat spreader 54 can be direct bonded to the top surface 53S1 of the processor die 53 through the use of an oxide-to-oxide bond. An interfacial layer (TIM layer 57) may be optionally incorporated between the processor die 53 and the first heat spreader 54. When the metal plate is used as the first heat spreader 54, the first heat spreader 54 can be directly bonded to the top surface of the processor die 53 through the use of a metal die attach or bonding layer such as a solder in conjunction with a backside surface metallurgy (BSM) layer deposited on the backside of the processor. BSM serves the functions of ohmic contact with low resistance, barrier to prevent inter-diffusion of metals (e.g., Cu or Au into Si) and good thermal conductivity. BSM candidates include
Ti, Cr or TiW (adhesion and barrier layer; 50-200 nm) directly on Si;
Ni, NiV or Mo (diffusion barrier; 200-500 nm); Cu,
Ag or Au (final conductive layer; 1-5μm) or
a combination thereof.

A BSM deposition process can include IC backside cleaning & preparation (e.g., a wet clean such as HF dip to remove native oxide, plasma clean such as using Ar or H2 plasma, etc.); metal deposition (e.g., sputtering, evaporation, electroplating, etc.); and annealing as needed.

Since the semiconductor dies 501 are disposed on the interposer 52 in an upright fashion (i.e., with their first sidewalls 501S1 attached to the memory controller 507), the memory stack 50 is substantially taller than the processor die 53, and the processor die 53 and the memory stack 50 defines a height difference H between the top surface of the processor die 53 and the second sidewall 501S2 of each of the semiconductor dies 501. In some embodiments, with the thickness of the processor die 53 being about 750 μm and the height of the memory stack 50 being about 5.25 mm, the height difference H between the top surface of the processor die 53 and the second sidewall of each of the semiconductor dies 501 can be in a range of about 4 to 5 mm. When the silicon fin structure is used as the first heat spreader 54, the height of the first heat spreader 54 can be less than the height difference H. When the metal plate is used as the first heat spreader 54, the height of the first heat spreader 54 can be designed to be substantially equal to the height difference H. In some embodiments, the semiconductor package structure 5 further includes a molding material 56 disposed on the first substrate 51 and the interposer 52, and encapsulating the memory stack 50, the processor die 53 and the first heat spreader 54.

In some embodiments, the liquid cooling structure 55 includes a cover 551 over the first heat spreader 54, wherein the first heat spreader 54 further includes a second surface 54S2 facing the cover 551, with a surface area of the second surface 54S2 of the first heat spreader 54 greater than that of the first surface 54S1 of the first heat spreader 54. In some embodiments, the cover 551 and the first heat spreader 54 forms a first cavity 542 (see FIG. 5B) including trenches allowing the liquid coolant to flow through. In some embodiments, the cover 551 has a bottom surface 551S1 thermally coupled to the second surface 54S2 of the first heat spreader 54 to transfer heat from the first heat spreader 54. In some embodiments, the bottom surface 551S1 of the cover 551 is in contact with the top surface 54S2 of the heat spreader 54. In some embodiments, the cover 551 at least partially overlaps the trenches 542.

In some embodiments, the liquid cooling structure 55 further includes an inlet 554 and an outlet 555 as shown in FIG. 5B, wherein the inlet 554 and the outlet 555 are coupled thermally with the trenches 542 through the liquid coolant. The liquid coolant can flow from the inlet 554 to the outlet 555 through the trenches 542, thereby dissipating heat generated by the memory stack 50 and the processor die 53. In some embodiments, the inlet 554 is located on a sidewall of the liquid cooling structure 55, and the outlet 555 is located on another sidewall of the liquid cooling structure 55. The direction pointing from the inlet 554 to the outlet 555 can be substantially aligned with the direction pointing from the memory stack 50 toward the processor die 53. In some embodiments, where the processor die 53 accounts for a major heat source, the inlet 554 can be arranged closer to or on the same side as the cooler memory stack 50 to increase the heat dissipation efficiency of the liquid coolant.

Referring to FIG. 5B, in some embodiments, t he second surface 54S2 of the first heat spreader 54 includes a plurality of fins 541 or trenches 542 arranged in parallel and extending in a direction of a flow of the liquid coolant towards the memory stack 50. For example, the fins 541 extend along a first direction (X-direction), forming a plurality of trenches 542 extending along the first direction (X-direction). In the present embodiment, the trenches 542 are separated from each other by the fins 541, and the inlet 554 is thermally coupled with the trenches 542, allowing the liquid coolant to flow through each trench 542. In some embodiments, the cover 551 and the first heat spreader 54 define the trenches or the cavity 542 allowing the liquid coolant to flow through. According to some embodiments, the first surface 54S1 may be a relatively flat surface free of any microstructures. Thus, the fins 541 and the trenches 542 can provide a greater surface area for the second surface 54S2 compared to that of the first surface 54S1. The fins 541 of the first heat spreader 54 can be designed in various configurations. More than one inlet and more than one outlet can also be considered. The present disclosure is not intended to be limited thereto.

Referring to FIG. 5A, in some embodiments, the liquid cooling structure 55 further includes a second heat spreader 552 including a third surface 552S1 facing the second sidewall 501S2 of each of the semiconductor dies 501 and a fourth surface 552S2 opposite to the third surface 552S1 with a surface area of the fourth surface 552S2 greater than that of the third surface 552S1. The second heat spreader 552 is configured to prevent the liquid coolant from contacting the second sidewall 501S2 of each of the semiconductor dies 501, wherein the cover 551 and the second heat spreader 552 together define a second cavity 553 allowing the liquid coolant to flow through. In some embodiments, where the second heat spreader 552 is used as a heat spreading element between the memory stack 50 and the liquid coolant, the adhesion layer 502 may include a non-waterproof material. For example, the adhesion layer 502 can be made of a polymer.

In some embodiments, the second heat spreader 552 serves as a heat spreading element between the liquid coolant and the memory stack 50 with a desirable thermal conductivity. For example, the material to form the second heat spreader 552 can include Cu, SiC, etc. and a TIM. In some embodiments, the second heat spreader 552 is in direct contact with the second sidewall 501S2 of each semiconductor die 501. In some embodiments, the second heat spreader 552 is in direct contact with or is attached to the TIM layer 503 adjacent to the second sidewall 501S2 of the semiconductor dies 501. In some embodiments, the TIM layer 503 can extend upward to the second sidewall 501S2 of each of the semiconductor dies 501 of the memory stack 50 to form a laterally extending TIM layer similar to the laterally extending high thermal conductivity layer 423 illustrated in FIG. 4.

In some embodiments, from a top view, the second heat spreader 552 covers the entire memory stack 50 and partially covers the molding material 56 surrounding the memory stack 50. In some embodiments, the second heat spreader 552 is in direct contact with or is attached to the molding material 56 surrounding the memory stack 50. In some embodiments, the second heat spreader 552 partially overlaps the first heat spreader 54, preventing the liquid coolant from coming into contact with the molding material 56. In some embodiments, the second cavity 553 is thermally coupled with the trenches 542 through the sidewall of the second heat spreader 552.

The cavity or trench formed on the second surface 54S2 of the first heat spreader 54 can be designed in various configurations. For example, as shown in FIG. 5B, the trenches 542 are separated by the fins 541 and extend along the X-direction to allow the liquid coolant to flow through. In some embodiments, as shown in FIG. 5C, a plurality of protrusions 541′ (e.g. pillars, columns or dendritic structures for maximal surface area such as those found in forming vapor chambers) are disposed on the second surface 54S2 of the first heat spreader 54, thereby defining a cavity 542′ allowing the liquid coolant to flow through. In some embodiments, the liquid coolant can directly contact the memory stack 50 or the processor die 53. Referring to FIG. 5D, another configuration of the semiconductor package structure 5 is shown. In some embodiments, the semiconductor package structure 5 as shown in FIG. 5D is free of any heat spreader on the top surface 53S1 of the processor die 53, and the liquid coolant flowing through the liquid cooling structure 55 can directly contact and cool the top surface 53S1 of the processor die 53 to dissipate heat generated by the processor die 53.

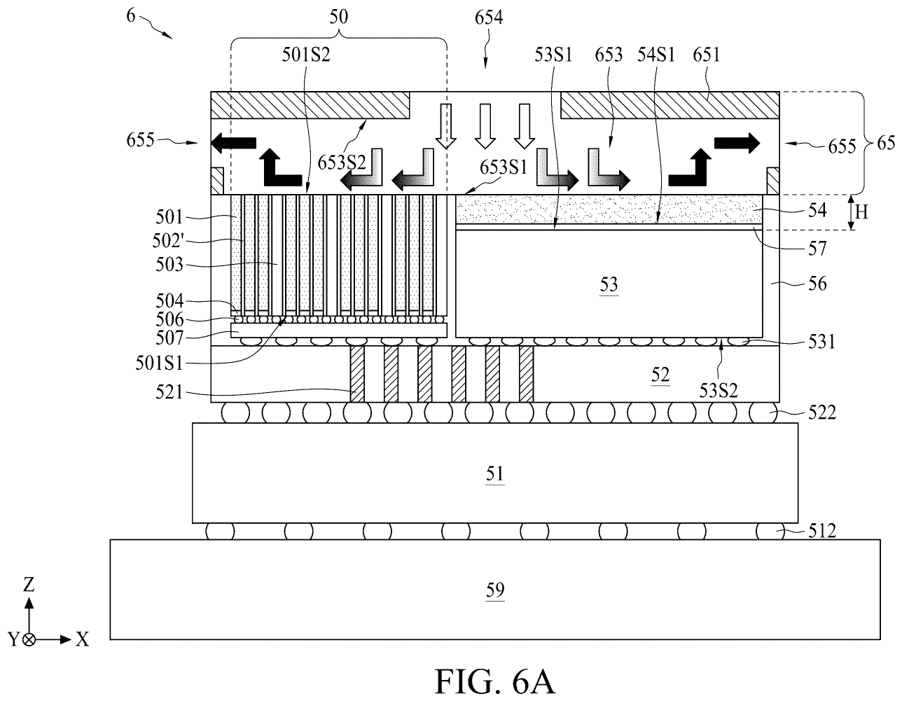

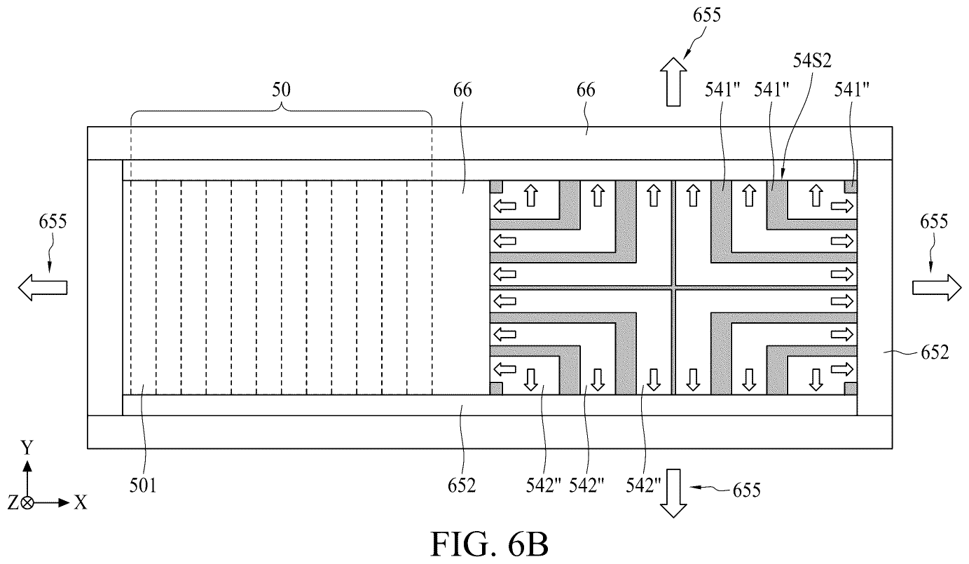

FIG. 6A shows a side view of a semiconductor package structure 6, and FIG. 6B shows a top view of the semiconductor package structure 6, according to some embodiments of the present disclosure. In the present embodiment, the memory stack 50, the semiconductor die 501, the bonding layer 502′, the HTC TIM layer 503, the edge pad 504, the bump 506, the memory controller die 507, the first substrate 51, the interposer 52, the processor die 53, the first heat spreader 54, the molding material 56, and the TIM layer 57 are basically similar to those describe in the embodiment described with reference to FIG. 5A. Thus, descriptions of these similar features are omitted for brevity.

In some embodiments, the liquid cooling structure 65 includes a cover 651 over the second sidewall 501S2 of each of the semiconductor dies 501 of the memory stack 50, wherein the cover 651 and the memory stack 50 together define a third cavity 653 allowing a liquid coolant to flow through and contact the second sidewall 501S2 of the semiconductor dies 501. In some embodiments, a bottom surface 653S1 of the third cavity 653 is defined by the first heat spreader 54, the molding material 56 and the memory stack 50. The top surface 653S2 of the third cavity 653 is defined by the cover 651. In some embodiments, the liquid cooling structure 65 includes an inlet 654 on the cover 651 and an outlet 655 on at least one side of the liquid cooling structur e 65. The configuration of the inlet 654 and the outlet 655 can be designed for achieving optimized cooling efficiency. In some embodiments, where the processor die 53 may require more heat dissipation than the memory stack 50, the inlet 654 can be located proximal to the processor die 53 and the first heat spreader 54 for increasing the heat dissipation efficiency. The inlet 654 may be overlapped with the processor die 53 or the first heat spreader 54 from a top-view perspective. In some embodiments, the inlet 654 is located between the memory stack 50 and the first heat spreader 54, and the two outlets 655 are respectively located on a first side corresponding to the memory stack 50 and a second side corresponding to the first heat spreader 54.

In some embodiments, the structures shown in FIG. 6A to FIG. 6B can be referred to as an impinging liquid cooling scheme. The cooling scheme of impinging liquid cooling includes using a high-speed fluid jet or spay that directly strikes the hot chip (processor die 53) to increase heat transfer efficiency. One feature of the proposed impinging liquid cooling is that the liquid coolant directly hits on the top surface of the processor die 53 to enhance heat transfer and enable localized cooling of hot spots. In some embodiments, to utilize the impinging cooling scheme, the memory stack 50, of which the second sidewall 501S2 is exposed to the liquid coolant, may need a special hermetic bonding material (e.g., an oxide, ceramic and metallic material with backside surface metallurgy as warranted) and even a hermetic RDL (based on, for example, oxide/Cu) to ensure that the liquid does not permeate into the space between adjacent semiconductor dies 501. In this embodiment, the bonding layer 502′ can be formed through a hybrid bonding process, which forms hermetic oxide-oxide bonds and metal-metal bonds at the interface between the adjacent semiconductor dies 501. In some embodimen ts, at least one of the top surface and the bottom surface of each of the semiconductor dies 501 includes an oxide layer or an oxide-oxide bonding layer to form an oxide-oxide bond with an adjacent one of the semiconductor dies 501. By forming oxide-oxide bonds between the semiconductor dies 501, the interface between adjacent semiconductor dies 501 can be waterproof, ensuring the integrity of the semiconductor package structure 6 when the impinging cooling scheme is used. In some embodiments, one can pre-coat the second sidewall of the memory stack with a conformal waterproof coating such as a thin (a few micrometers thick), pin-hole-free, chemical vapor deposited parylene layer which imparts only a small increase in thermal resistance in rendering the memory stack waterproof. This largely opens up the window in RDL and bonding/sealing material section. Analogously, one can apply the same concept to the processor to enable the removal of the heat spreader deposited thereon.

In some embodiments, as shown in FIG. 6B, a plurality of HTC sheets 541″ are disposed on the second surface 54S2 of the first heat spreader 54, thereby defining trenches 542″ allowing the liquid coolant to flow through. For the first heat spreader 54 illustrated in FIG. 6A and FIG. 6B, the inlet 654 can be located proximal to a center of the first heat spreader 54, allowing the liquid coolant with a lower temperature to contact the first heat spreader 54 earlier.

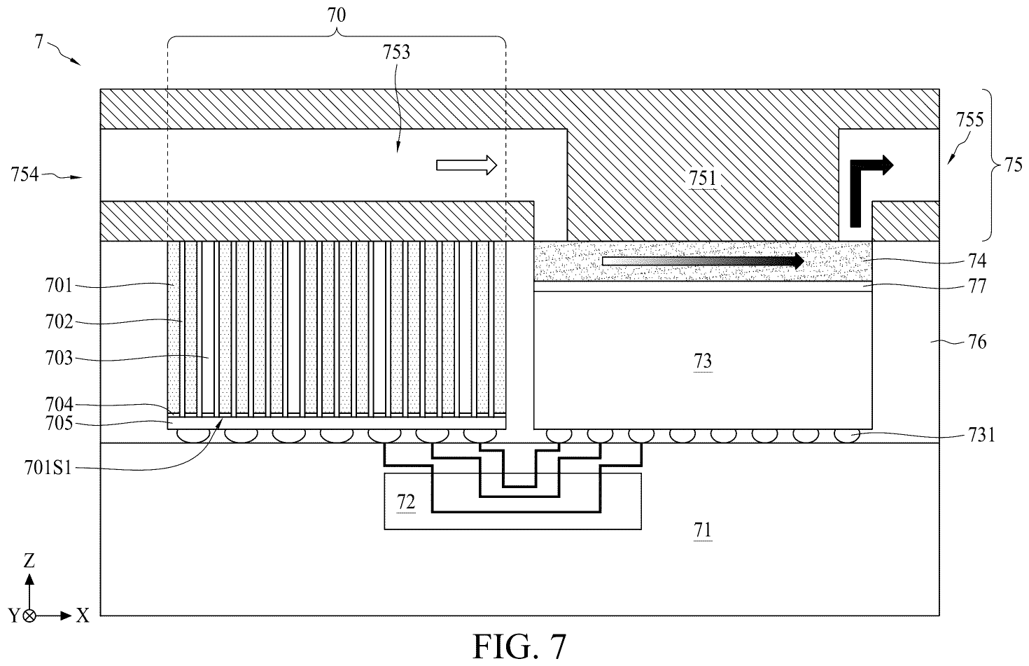

FIG. 7 shows a semiconductor package structure 7 with a memory stack 70 and a liquid cooling structure 75, according to some embodiments of the present disclosure. In the present embodiment, the memory stack 70 includes a plurality of semiconductor dies 701, adhesive layers 702 between adjacent semiconductor dies 701, edge pads 704 located on the first sidewall 701S1 of each semiconductor die 701, and an RDL 705 arranged under the memory stack 70 and electrically connected to the plurality of edge pads 704 of each of the semiconductor dies 701. The abovementioned features of the memory stack 70 are similar to those of the memory stack 50 or 60 in many respects, and descriptions of these features are omitted for brevity.

In contrast to the memory stacks 50 and 60 illustrated in FIG. 5A and FIG. 6A, respectively, the memory stack 70 includes an RDL 705 under the edge pads 704 of the semiconductor dies 701, and but is not connected to a memory controller die. The RDL 705 can be similar to the RDLs 202 and 302 illustrated in FIGS. 2G to 2H and 3J to 3M, respectively. However, in some embodiments, the memory stack 70 includes memory controller dies 703 within the memory stack 70 and over the substrate 71. The memory controller die 703 can also include edge pads 704 having a configuration similar to that illustrated in FIG. 2A or similar to the edge pads 704 of the semiconductor dies 701. In some embodiments, the memory controller die 703 is electrically connected to the semiconductor dies 701 through the RDL 705 using the edge pads 704.

In some embodiments, the semiconductor dies 701 can be divided into several groups of semiconductor dies 701 separated by the memory controller dies 703 with each memory controller die 703 configured to control a respective group of semiconductor dies 701 (memory dies). Therefore, the decentralized architecture of the memory stack 70 can achieve a higher data transmission speed between the semiconductor dies 701 and the respective memory controller die 703. Compared to the architecture of a single memory controller die 507 under the semiconductor dies 501 for handling all of the semiconductor dies 501 (memory die) as shown in FIG. 5A, the package structure 7 can present a more efficient design option.

In some embodiments, the substrate 71 includes an embedded interconnection die 72 electrically connect ing the processor die 73 and a portion of the plurality of edge pads 704 of at least one of the semiconductor dies 701. The embedded interconnection die 72 may be integrated with the substrate 71 and configured to electrically connect the semiconductor dies 701 and the processor die 73. The embedded interconnection die 72 may be formed of a silicon interconnect bridge whose RDL is built by fine-line/space BEOL processes with or without through via (not shown).

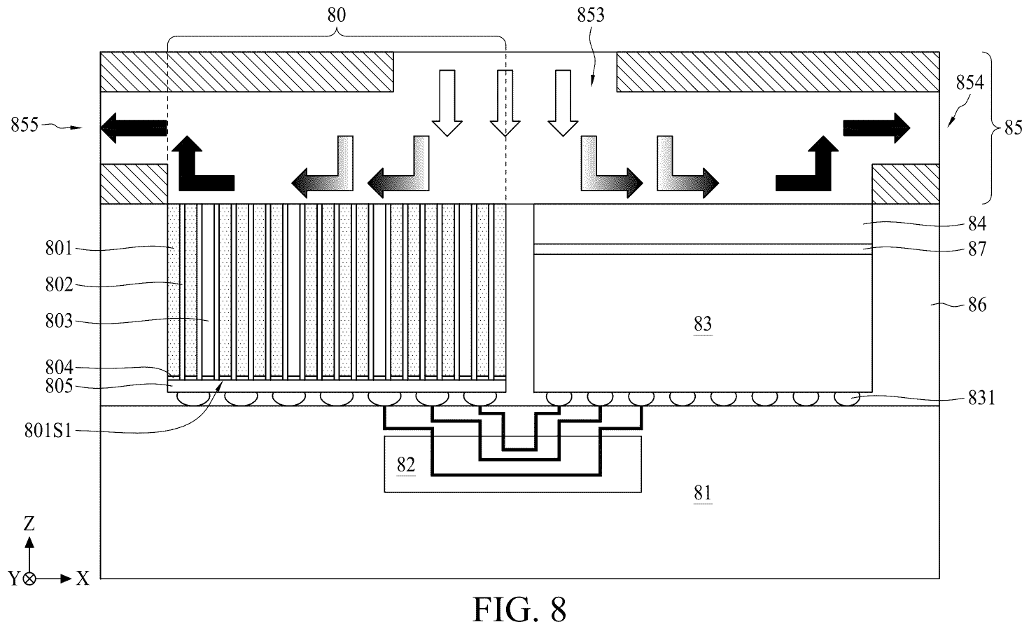

FIG. 8 shows a semiconductor package structure 8 with a memory stack 80 and a liquid cooling structure 85, according to some embodiments of the present disclosure. In the present embodiment, the memory stack 80 includes a plurality of semiconductor dies 801, adhesive layers 802 between adjacent semiconductor dies 801, edge pads 804 located on the first sidewall 801S1 of each semiconductor die 801, and an RDL 805 arranged under the memory stack 80 and electrically connected to the plurality of edge pads 804 of each of the semiconductor dies 801. The abovementioned features of the memory stack 80 are similar to those of the memory stack 70. The liquid cooling structure 85 is basically the same as the impinging cooling structure of the embodiment in FIG. 6A. Thus, the descriptions of the above features are omitted for brevity.

In the present disclosure, the conventional HBMs are replaced with a proposed massively parallel 3D memory (MP3M) structure, which can optionally be bonded to the control IC using a chip side surface. In the MP3M, the cooling structure is incorporated with a high-thermal-conductivity (HTC) finned heat spreader on the backside of the processor chip, or both the processor chip and the MP3M. The MP3M and the processor are cooled using either the direct-to-chip liquid (e.g., water) cooling scheme or the impinging liquid cooling scheme. The chip side surface connected MP3M can support as many as 87,040 I/Os using the smaller of the HBM2E pitch (29 μm) as an example, which is more than enough.

In a 2.5D IC containing side-surface-bonded memory stacks, these interconnections can be connected to other chip-side-surface interconnections on the other chip side surfaces in support of higher I/Os although only interconnections on one chip side surface are shown in FIG. 5A to FIG. 8). With the use of the disclosed MP3M, one can enjoy the following benefits which mitigate the aforementioned issues concerning conventional HBMs: 1) it is easier to get higher yields with smaller and thicker memory dies (e.g., of the same width as the HBM2E DRAM but only half of its length using HBM2E; 2) it supports more memory choices (including DDR5); 3) the face-to-face, point-to-point, logic-to-memory interconnects between the bonding pads of the chip-side-surface RDL and matching pads of the control IC reduces the interconnection length, and minimizes capacitive, inductive coupling and electrical impedance, resulting in reduced switching currents and reflections and power consumption; 4) a lower thermal impedance is achieved; 5) it supports input pads for power switching of individual dies (and because each memory die is independent, one physical layer (PHY) can be sufficient for each die); 6) a wide word access for increased bandwidth; 7) it supports almost unlimited I/O counts on the RDL (e.g., PI/Cu or oxide/Cu layers) of a chip side surface as the pad/bump pitch can be reduced to below 29 μm and also much faster data transfer, thereby allowing vintage memory devices to compete with leading-edge memory devices in HBMs; 8) smaller memory players can join the race with the big companies using more readily accessible RDL and flip chip technologies from OSATS (Outsourced Semiconductor Assembly and Test); 9) it provides an opportunity to work with more players besides the big companies on memory customization or optimization for AI, HPC and edge AI; and 10) there is no need to use the costly copper hybrid bonding.

Furthermore, overheating in middle and bottom memory tiers in the HBM stacks where cooling is taking place from the backside of the top DRAM can be prevented as the heat will now be conducted through silicon in the MP3M with a thermal conductivity of more than approximately 100 times that of silicon dioxide (rather than a combination of silicon and the poorly heat dissipating silicon dioxide as in the case of conventional HBM stacks) and furthermore with the use as needed of high-thermal-conductivity, low-coefficient-of-thermal-expansion substrates/interposers (with or without through vias but with RDLs) and/or HTC spacers. Additionally, the proposed structure supports easy scalability to larger numbers of memory dies while not having to worry about the overheating effects. It is also possible to do away with the HTC finned HS attached to the backside of the GPU to allow the liquid coolant to be directly in contact with the GPU when a hermetic material set is used in forming the RDLs, the bonding layers, etc.

In this disclosure, cooling of very-high-power GPUs can be achieved using a combination of a HTC finned structure, a direct-to-chip cooling arrangement which can handle a power density as high as 7 W/mm², an impinging flow arrangement and other suitable means including liquid immersion cooling and liquid nitrogen cooling in the extreme. Although not shown, the structures and processes disclosed herein are equally applicable to applications involving copper hybrid bonding in replace of flip chip bonding; TSVs; RDL on one side or two sides (top and bottom sides) of the interconnect spacer/interposer/substrate; partial through vias in ICs and/or spacers; edge connectors in ICs and/or spacers; and/or 3D ICs involving integration of MP3Ms on the GPU or other types of processors in the package thickness direction.

What is claimed is:

1. A semiconductor package structure, comprising:
a memory stack comprising:
a plurality of semiconductor dies horizontally separate with each other, wherein each semiconductor die comprises a top surface, a bottom surface opposite to the top surface, and four sidewalls with a first sidewall, a second sidewall, a third sidewall and a fourth sidewall, wherein the second sidewall is opposite to the first sidewall, and a plurality of edge pads arranged on the first sidewall of each semiconductor die; wherein the area of the bottom surface or the top surface is larger than that of anyone of the four sidewalls; and
a substrate under the memory stack and electrically connected to the plurality of edge pads of each of the semiconductor dies;
a processor die over the substrate and adjacent to the memory stack, comprising a top surface facing away from the substrate; and
a liquid cooling structure over the memory stack and the processor die, and thermally coupled to both the memory stack and the processor die via the second sidewall of each of the semiconductor dies and the top surface of the processor die.

2. The semiconductor package structure of claim 1, further comprising:
a first heat spreader over the processor die, wherein a first surface of the first heat spreader facing towards the processor die is substantially leveled with the top surface of the processor die.

3. The semiconductor package structure of claim 2, wherein the liquid cooling structure comprises:
a cover over the first heat spreader, wherein the first heat spreader further includes a second surface facing the cover with a surface area of the second surface greater than a surface area of the first surface, wherein the cover and the first heat spreader together define a first cavity allowing a liquid coolant to flow through.

4. The semiconductor package structure of claim 3, wherein the liquid cooling structure further comprises:
a second heat spreader including a third surface facing the second sidewall of each of the semiconductor dies and a fourth surface opposite to the third surface with a surface area of the fourth surface greater than a surface area of the third surface, wherein the second heat spreader is configured to prevent the liquid coolant from contacting the second sidewall of each of the semiconductor dies, and wherein the cover and the second heat spreader together define a second cavity allowing the liquid coolant to flow through.

5. The semiconductor package structure of claim 4, wherein the memory stack further comprises an adhesive layer between the top surface of a semiconductor die and the bottom surface of an adjacent semiconductor die.

6. The semiconductor package structure of claim 3, wherein the second surface of the first heat spreader comprises a plurality of trenches extending in a direction of a flow of the liquid coolant.

7. The semiconductor package structure of claim 3, wherein the liquid cooling structure comprises:
a cover over the second sidewall of each of the semiconductor dies of the memory stack, wherein the cover and the memory stack together define a third cavity allowing the liquid coolant to flow through and contact the second sidewall of the semiconductor dies.

8. The semiconductor package structure of claim 1, wherein the liquid cooling structure further comprises an inlet and an outlet.

9. The semiconductor package structure of claim 7, further comprising a bonding layer over the top surface of the processor die and configured to bond the processor die and the first surface of the first heat spreader.

10. The semiconductor package structure of claim 1, wherein the memory stack further comprises:
an upward extending high thermal conductivity layer between two adjacent semiconductor dies, wherein the thermal conductivity of the upward extending high thermal conductivity layer is higher than that of SiO₂.

11. A semiconductor package structure comprising:
a memory stack comprising:
a plurality of semiconductor dies horizontally separate with one another, wherein each semiconductor die comprises a top surface, a bottom surface opposite to the top surface, and four sidewalls with a first sidewall, a second sidewall, a third sidewall and a fourth sidewall, wherein the second sidewall is opposite to the first sidewall, and a plurality of edge pads arranged on the first sidewall of each semiconductor die, wherein the area of the bottom surface or the top surface is larger than that of anyone of the four sidewalls;
a substrate under the memory stack and electrically connected to the plurality of edge pads on the first sidewall of each of the semiconductor dies;
a processor die over the substrate, comprising a top surface and a bottom surface opposite to the top surface, and adjacent to the memory stack, wherein the processor die and the memory stack defines a height difference between the top surface of the processor die and the second sidewall of each of the semiconductor dies; and
a liquid cooling structure over the memory stack and the processor die.

12. The semiconductor package structure of claim 11, further comprising:
a first heat spreader over the processor die, wherein a first surface of the first heat spreader facing the processor die is substantially coplanar with the top surface of the processor die.

13. The semiconductor package structure of claim 12, wherein the liquid cooling structure comprises:
a cover over the first heat spreader, wherein the first heat spreader further includes a second surface facing the cover with a surface area of the second surface greater than a surface area of the first surface, wherein the cover and the first heat spreader together define a cavity allowing a liquid coolant to flow through.

14. The semiconductor package structure of claim 13, wherein the liquid cooling structure further comprises:
a second heat spreader including a third surface facing the second sidewall of each of the semiconductor dies and a fourth surface opposite to the third surface with a surface area of the fourth surface greater than a surface area of the third surface, wherein the second heat spreader is configured to prevent a liquid coolant from contacting the second sidewall of each of the semiconductor dies.

15. The semiconductor package structure of claim 12, wherein the liquid cooling structure comprises:
a cover over the first heat spreader and the second sidewall of each of the semiconductor dies, wherein the cover, the first heat spreader and the memory stack together define a cavity allowing a liquid coolant to flow through.

16. The semiconductor package structure of claim 11, further comprising:
a memory controller die over the substrate and under the memory stack with the memory controller die electrically connected to the plurality of edge pads of each of the semiconductor dies.

17. The semiconductor package structure of claim 11, further comprising:
a memory controller die within the memory stack and over the substrate with the memory controller die electrically connected to the plurality of edge pads of each of the semiconductor dies.

18. The semiconductor package structure of claim 11, wherein the substrate comprises:
a laminate substrate under the memory stack and the processor die; and
an interposer between the laminate substrate and the memory stack and the processor die, wherein the interposer comprises a plurality of through vias traversing the thickness of the interposer.

19. The semiconductor package structure of claim 11, further comprising:
a redistribution layer under the memory stack and electrically connected to the plurality of edge pads of each of the semiconductor dies.

20. The semiconductor package structure of claim 11, wherein the substrate comprises an embedded interconnection die electrically connecting the processor die and a portion of the plurality of edge pads of at least one of the semiconductor dies of the memory stack.
